(19) United States
(12) Patent Application Publication
(10) Pub. No.: US 2007/0075403 A1
(43) Pub. Date: Apr. 5, 2007

(54) Functional structural element, method of manufacturing functional structural element, and substrate for manufacturing functional structural body

(75) Inventors: Yukio Sakashita, Ashigara-Kami-Gun (JP); Takamichi Fujii, Ashigara-Kami-Gun (JP); Yoshinobu Nakada, Ashigara-Kami-Gun (JP); Yoshikazu Hishinuma, Ashigara-Kami-Gun (JP)

Correspondence Address: BIRCH STEWART KOLASCH & BIRCH, PO BOX 747, FALLS CHURCH, VA, 22040-0747, US

(73) Assignee: FUJI PHOTO FILM CO., LTD.

(21) Appl. No.: 11/529,518

(22) Filed: Sep. 29, 2006

(30) Foreign Application Priority Data
Sep. 30, 2005 (JP) 2005-288820

(51) Int. Cl. H01L 29/06

(52) U.S. Cl. 257/626

(57) ABSTRACT

The functional structural element includes: a substrate member which has a surface made of directionally solidified silicon; and a functional structural body which is made of a functional material and is formed on the surface of the substrate member.

### BACKGROUND OF THE INVENTION

1. Field of the Invention

The present invention relates to a functional structural element, a method of manufacturing a functional structural element, and a substrate for manufacturing a functional structural body.

2. Description of the Related Art

Extensive research has been carried out using functional film elements formed by using a functional material, such as electronic ceramic material, or the like. In general, in order to satisfactorily maximize the functions of the functional film element, heat treatment at a relatively high temperature (for example, approximately 500° C. to 1000° C.) is required, and therefore the substrate onto which the functional film is formed needs to have heat resistance. Monocrystalline silicon wafers are commonly used as relatively inexpensive substrates having heat resistance. The monocrystalline silicon wafers are sliced from a silicon ingot manufactured by the Czochralski method. In the Czochralski method, it is difficult to achieve a large silicon ingot, and the diameter thereof is approximately 300 mm, at maximum.

As a material for substrates formable to large sizes, directionally solidified polycrystalline silicon (directionally solidified silicon, columnar polycrystalline silicon) has been proposed (see Japanese Patent Application Publication No. 2003-286024). Directionally solidified silicon has merits in that it can be formed to a large size and is inexpensive.

However, Japanese Patent Application Publication No. 2003-286024 merely discloses the use of directionally solidified silicon in a solar battery substrate.

### SUMMARY OF THE INVENTION

The present invention has been contrived in view of the foregoing circumstances, an object thereof being to provide a functional structural element, a method of manufacturing a functional structural element, and a substrate for manufacturing a functional structural body.

In order to attain the aforementioned object, the present invention is directed to a functional structural element, comprising: a substrate member which has a surface made of directionally solidified silicon; and a functional structural body which is made of a functional material and is formed on the surface of the substrate member.

It is possible to include a further material layer, between the substrate member and the functional structural body.

According to this aspect of the present invention, it is possible to obtain the functional structural element of a large size by using the directionally solidified silicon substrate, which can readily be formed to a large size. Moreover, since the price per unit surface area of the directionally solidified silicon substrate is inexpensive, then it is possible to reduce the cost of the functional structural element. Furthermore, by forming the directionally solidified silicon substrate to a large size, it is possible to manufacture a large amount of functional structural elements, from one substrate of directionally solidified silicon, by one manufacturing process, and therefore it is possible to reduce the unit cost of the functional structural element.

Preferably, the surface of the substrate member is a Si(001) surface.

Preferably, the functional structural element further comprises a buffer layer which is formed between the substrate member and the functional structural body, wherein the functional material is epitaxially grown onto the buffer layer and forms the functional structural body.

According to this aspect of the present invention, by forming the buffer layer between the directionally solidified silicon substrate and the functional structural body, it is possible to suppress diffusion of oxygen or the elements of the functional material to the surface of the directionally solidified silicon substrate, compared to a case where the functional material is deposited directly onto the surface of the directionally solidified silicon substrate. Therefore, it is possible to deposit the functional material more stably, and furthermore, it is also possible to improve the quality of the functional structural body. Moreover, in the case where the directionally solidified silicon substrate and the functional structural body have different lattice constants, it is possible to improve the quality of the functional structural body by providing the buffer layer of a material having the intermediate characteristics between those of directionally solidified silicon and the functional material (for example, a material having a lattice constant between that of directionally solidified silicon and that of the functional material).

Preferably, the buffer layer is made of a material including at least one of yttria-stabilized zirconia, celia, magnesium aluminate, and alumina.

Preferably, the functional material includes at least one of a piezoelectric material, a pyroelectric material and a ferroelectric material. Preferably, the functional material includes a superconducting material. Preferably, the functional material includes a magnetic material. Preferably, the functional material includes a semiconductor material.

In order to attain the aforementioned object, the present invention is also directed to a method of manufacturing a functional structural element, comprising the steps of: forming a substrate member having a surface made of directionally solidified silicon; and forming a functional structural body made of a functional material onto the surface of the substrate member.

It is also possible to form a further material layer additionally between the substrate member and the functional structural body.

According to this aspect of the present invention, it is possible to obtain the functional structural element of a large size by using a directionally solidified silicon substrate, which can readily be formed to a large size. Furthermore, since the price per unit surface area of the directionally solidified silicon substrate is inexpensive, then it is possible to reduce the cost of the functional structural element. Moreover, by forming the directionally solidified silicon substrate to a large size, it is possible to manufacture a large amount of functional structural elements, from one substrate of directionally solidified silicon, by one manufacturing process, and therefore it is possible to reduce the unit cost of the functional structural element.

In order to attain the aforementioned object, the present invention is also directed to a method of manufacturing a functional structural element, comprising the steps of: forming a substrate member having a surface made of directionally solidified silicon; forming a buffer layer onto the surface of the substrate member; and forming a functional structural body by epitaxially growing a functional material onto the buffer layer.

According to this aspect of the present invention, by forming the buffer layer between the directionally solidified silicon substrate and the functional structural body, it is possible to suppress diffusion of oxygen or the elements of the functional material to the surface of the directionally solidified silicon substrate, compared to a case where the functional material is deposited directly onto the surface of the directionally solidified silicon substrate. Therefore, it is possible to deposit the functional material more stably, and furthermore, it is also possible to improve the quality of the functional structural body. Moreover, in the case where the directionally solidified silicon substrate and the functional structural body have different lattice constants, it is possible to improve the quality of the functional structural body by providing the buffer layer of a material having the intermediate characteristics between those of directionally solidified silicon and the functional material (for example, a material having a lattice constant between that of directionally solidified silicon and that of the functional material).

In order to attain the aforementioned object, the present invention is also directed to a substrate for manufacturing a functional structural body, the substrate comprising: a substrate member which has a surface made of directionally solidified silicon; and a buffer layer which is formed on the surface of the substrate member, a functional structural body to be formed on the buffer layer.

Preferably, the buffer layer is made of a material including at least one of yttria-stabilized zirconia, celia, magnesium aluminate, and alumina.

According to the present invention, it is possible to obtain the functional structural element of a large size by using the directionally solidified silicon substrate, which can readily be formed to a large size. Moreover, since the price per unit surface area of the directionally solidified silicon substrate is inexpensive, then it is possible to reduce the cost of the functional structural element. Further, by forming the directionally solidified silicon substrate to a large size, it is possible to manufacture a large amount of functional structural elements, from one substrate of directionally solidified silicon, by one manufacturing process, and therefore it is possible to reduce the unit cost of the functional structural element. Furthermore, in the case where the directionally solidified silicon substrate and the functional structural body have significantly different lattice constants, it is possible to improve the quality of the functional structural body by providing a buffer layer of a material having intermediate characteristics between those of directionally solidified silicon and the functional material (for example, a material having a lattice constant between that of directionally solidified silicon and that of the functional material).

### BRIEF DESCRIPTION OF THE DRAWINGS

The nature of this invention, as well as other objects and benefits thereof, is explained in the following with reference to the accompanying drawings, in which like reference characters designate the same or similar parts throughout the figures and wherein:

FIGS. 1A and 1B are diagrams showing a method of manufacturing a functional structural element according to a first embodiment of the present invention;

FIGS. 2A to 2C are diagrams showing a method of manufacturing a substrate made of directionally solidified silicon;

FIGS. 3A to 3C are diagrams showing a method of manufacturing a functional structural element according to a second embodiment of the present invention; and

FIGS. 4A to 4H are diagrams showing a method of manufacturing a piezoelectric actuator.

### DETAILED DESCRIPTION OF THE PREFERRED EMBODIMENTS

Functional structural elements, methods of manufacturing functional structural elements, and substrates for manufacturing functional structural bodies according to embodiments of the present invention are described with reference to attached drawings.

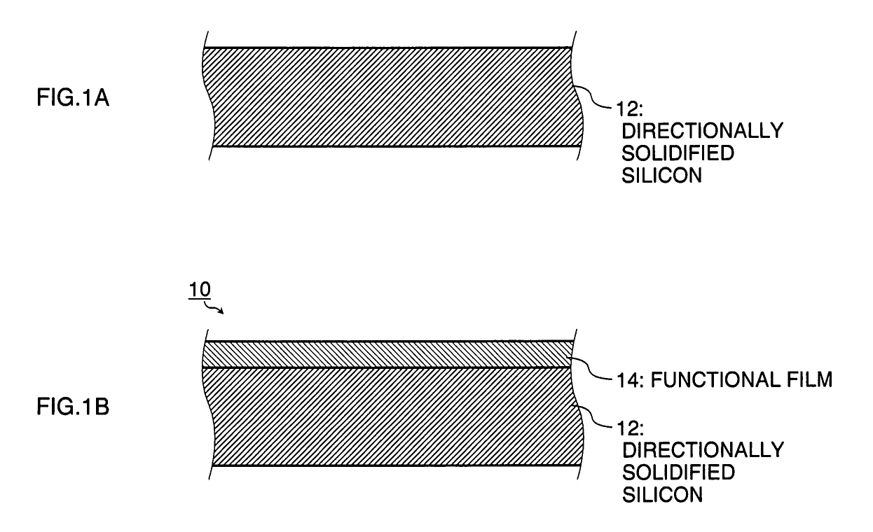

FIGS. 1A and 1B are diagrams showing a method of manufacturing a functional structural element according to a first embodiment of the present invention. FIGS. 1A and 1B are cross-sectional diagrams showing respective steps of a process for manufacturing a functional structural element.

Firstly, as shown in FIG. 1A, a substrate 12 made of directionally solidified silicon is prepared. For example, it is possible to prepare the substrate 12 using directionally solidified silicon (columnar crystal silicon) manufactured by JEMCO INC.

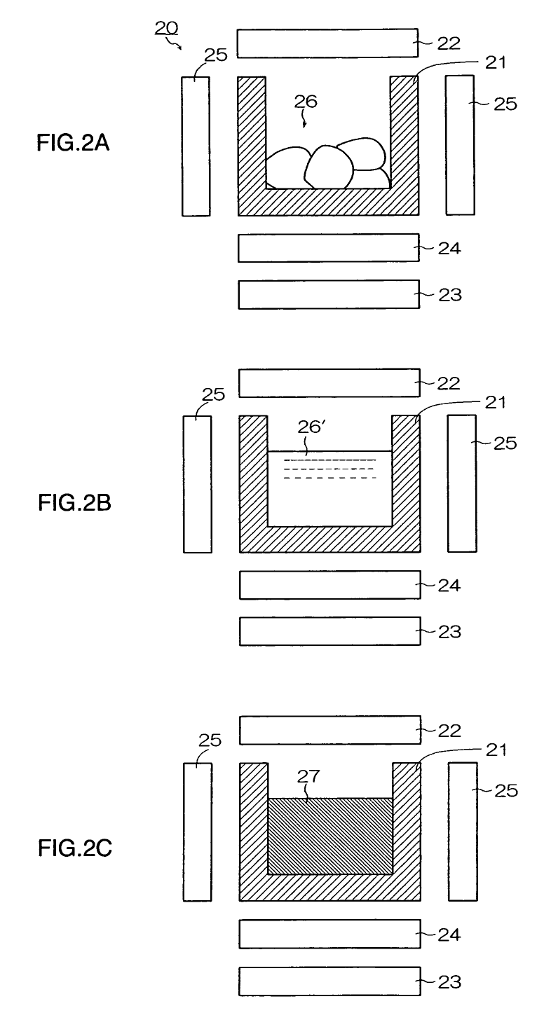

An embodiment of a process for manufacturing the substrate 12 made of directionally solidified silicon is described with reference to FIGS. 2A to 2C. FIGS. 2A to 2C are diagrams showing a method of manufacturing the substrate 12 made of directionally solidified silicon.

A silicon ingot manufacturing apparatus 20 shown in FIGS. 2A to 2C comprises: a crucible 21, which has a large horizontal cross-sectional area; a ceiling heater 22, which is disposed above the crucible 21; an underfloor heater 23, which is disposed below the crucible 21; a cooling plate 24, which is disposed between the crucible 21 and the underfloor heater 23; and a heat insulating material 25, which encompasses the periphery of the crucible 21. The ceiling heater 22 and the underfloor heater 23 are heaters which heat the crucible 21 in a planar fashion and have a structure formed by processing carbon heat generating bodies in a planar shape, for example. The silicon ingot manufacturing apparatus 20 described above is disposed inside a chamber (not shown) in which the internal gas can be controlled, in such a manner that oxidation of silicon material 26 during melting is prevented. For example, if a heat insulating material made of carbon fibers is used as the heat insulating material 25, then silicon carbide (SiC) may mingle with the molten silicon when melting in the crucible made of silica. Therefore, it is preferable that an apparatus for supplying inert gas to the crucible 21 is provided, thereby maintaining the interior of the crucible 21 in an inert atmosphere during the period of melting silicon.

As shown in FIG. 2A, the silicon material 26 is put into the crucible 21 so as to cover the bottom of the crucible 21, and is heated and melted by driving the ceiling heater 22 and the underfloor heater 23.

Thereupon, as shown in FIG. 2B, when the silicon material 26 melts completely into molten silicon 26′, a drive current applied to the underfloor heater 23 is halted or reduced, and a cooling medium (for example, water, or an inert gas such as argon (Ar) gas) is supplied to the cooling plate 24, thereby cooling the bottom of the crucible 21. Consequently, the molten silicon 26′ is cooled from the bottom of the crucible 21, thereby generating a crystal structure of directional solidification.

Then, the temperature of the ceiling heater 22 is lowered in stages or continuously by reducing a drive current applied to the ceiling heater 22 in stages or continuously, and the directionally solidified crystal structure is thereby grown further in the upward direction. Thus, as shown in FIG. 2C, a silicon ingot 27, which has the crystal structure of directional solidification and a large horizontal cross-sectional area, is obtained. The substrate 12 shown in FIG. 1A, which is made of directionally solidified silicon, is sliced from the silicon ingot 27 manufactured in the manner described above. The directionally solidified silicon substrate 12, manufactured as described above, has columnar crystal structure in which silicon is solidified in one direction, and the crystal grain boundaries are controlled and arranged in one direction. Furthermore, the total impurity density of the substrate 12 is approximately 10 ppm or less. In the directionally solidified silicon substrate 12 manufactured as described above, the silicon crystals are aligned to have Si(001) surfaces forming the surface of the substrate 12. In other words, the directionally solidified silicon substrate 12 is a Si(001) substrate. The method of manufacturing the directionally solidified silicon substrate 12 is not limited to the method described above.

Next, as shown in FIG. 1B, a structural body of functional material (functional film) 14 is formed on the substrate 12, thereby manufacturing a functional structural element 10. In the manufacturing step shown in FIG. 1B, it is possible to use the sputter deposition method, the chemical vapor deposition (CVD) method, the sol-gel method, the aerosol deposition (AD) method, and the like, as a method for manufacturing the functional film 14. The aerosol deposition method is a film formation method in which an aerosol containing powder (starting material powder) of a functional material is prepared and jetted from a nozzle toward a substrate, and is made to impact against the substrate, and consequently the starting material is deposited on the substrate. The aerosol deposition method may also be referred to as a jet deposition method or a gas deposition method.

According to the method of manufacturing the functional structural element in the present embodiment, it is possible to manufacture the functional structural elements 10 as described below, by forming the functional films 14 using the following functional materials. The types of the functional materials are not limited to those described below.

The functional material used to manufacture memory elements includes Pb(Zr, Ti)O₃, SrBi₂(Ta, Nb)₂O₉, Bi₄Ti₃O₁₂, or the like.

The functional material used to manufacture piezoelectric elements, such as actuators, includes Pb(Zr, Ti)O_{1/3}, Pb(Mg_{1/3}Nb_{2/3})O₃, Pb(Zn_{1/3}Nb_{2/3})O₃, Pb(Ni_{1/3}Nb_{2/3})O₃, or the like, or a solid solution of these.

The functional material used to manufacture pyroelectric elements, such as infrared sensors, includes Pb(Zr, Ti)O₃, (Pb, La)(Zr, Ti)O₃, or the like.

The functional material used to manufacture passive components, such as capacitors, includes BaSrTiO₃, (Pb, La)(Zr, Ti)O₃, or the like.

The functional material used to manufacture optical elements, such as photo switches, includes (Pb, La)(Zr, Ti)O₃, LiNbO₃, or the like.

The functional material used to manufacture superconducting elements, such as superconducting quantum interference devices (SQUID), includes YBa₂Cu₃O₇, Bi₂Sr₂Ca₂Cu₃O₁₀, or the like. Here, the SQUID is a highly sensitive magnetic sensor element using superconduction.

The functional material used to manufacture photoelectric transducers, such as solar batteries, includes amorphous silicon, a compound semiconductor, or the like.

The functional material used to manufacture micro magnetic elements, such as magnetic heads, includes PdPtMn, CoPtCr, or the like.

The functional material used to manufacture semiconductor elements, such as thin film transistors (TFT), includes amorphous silicon, or the like.

Next, it is preferable that heat treatment is carried out on the functional structural element 10 shown in FIG. 1B, in order to improve the functions of the functional film 14 by promoting grain growth in the functional film 14, and thereby improving the crystalline properties. For example, when manufacturing the functional film 14 of Pb(Zr, Ti)O₃, (Pb, La)(Zr, Ti)O₃, BaSrTiO₃, or the like, heat treatment is carried out at around 500° C. or above. When manufacturing the functional film 14 of SrBi₂(Ta, Nb)₂O₉, Bi₄Ti₃O₁₂, YBa₂Cu₃O₇, Bi₂Sr₂Ca₂Cu₃O₁₀, or the like, heat treatment is carried out at around 700° C. or above.

In the method of manufacturing the functional structural element according to the present embodiment, it is possible to achieve a large size of the functional structural element 10 described above, by using the directionally solidified silicon substrate 12, which can be formed readily to a large size. For example, by using a piezoelectric element or a semiconductor element, such as TFT, or the like, manufactured by means of the method of manufacturing the functional structural element 10 described above, it is possible to manufacture a large-size inkjet head or display.

Moreover, since the price per unit surface area of the directionally solidified silicon substrate 12 is inexpensive, then it is possible to reduce the cost of the functional structural element 10. Furthermore, by forming the directionally solidified silicon substrate 12 to a large size, it is possible to manufacture a large amount of functional structural elements 10, from one substrate 12 of directionally solidified silicon, by means of one manufacturing process. Therefore, it is possible to reduce the unit cost of the functional structural element 10.

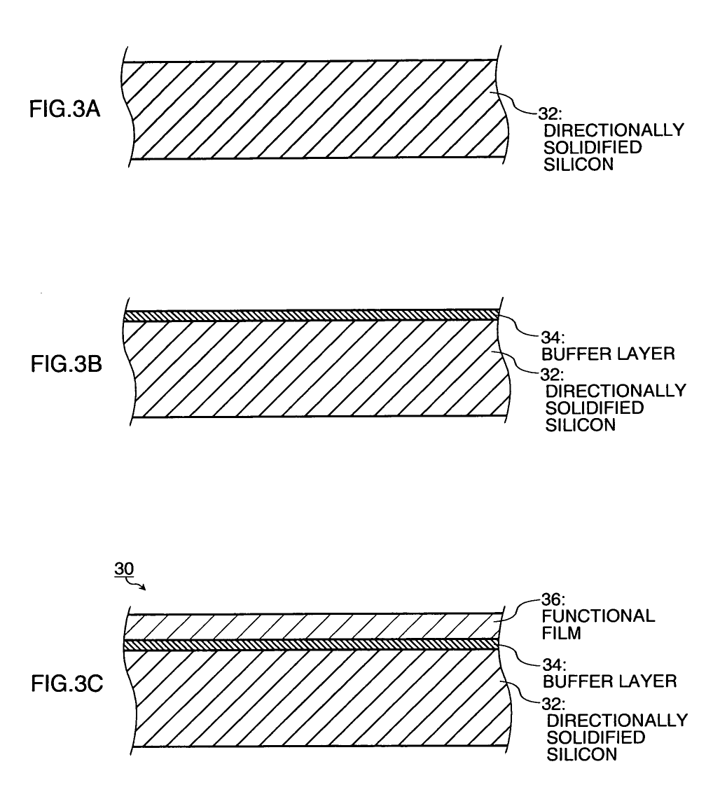

Next, a method of manufacturing a functional structural element according to a second embodiment of the present invention is described with reference to FIGS. 3A to 3C. FIGS. 3A to 3C are cross-sectional diagrams showing respective steps of a process for manufacturing a functional structural element.

Firstly, as shown in FIG. 3A, a substrate 32 made of directionally solidified silicon is prepared. The manufacturing steps of the directionally solidified silicon substrate 32 are similar to those of the first embodiment described above, and hence description thereof is omitted here.

Next, as shown in FIG. 3B, a buffer layer 34 is formed on the directionally solidified silicon substrate 32. The buffer layer 34 is formed from a material having a lattice constant that is suited to epitaxial growth of the functional material on the substrate 32. Here, the material of the buffer layer 34 is, for example, yttria-stabilized zirconia (YSZ) (ZrO₂+Y₂O), ceria (CeO₂), magnesium aluminate (MgAl₂O₄) or alumina (Al₂O₃), or a compound or mixture or alloy containing at least one of these. The method of forming the buffer layer 34 from the material described above is, for example, the sputter deposition method, the CVD method, the sol-gel method, the aerosol deposition method, or the like. Desirably, the buffer layer 34 is formed at a temperature which is slightly lower than the normal deposition temperature.

Next, as shown in FIG. 3C, a structural body of functional material (functional film) 36 is formed on the substrate 32, and heat treatment is carried out on the functional film 36 and the substrate 32, thereby obtaining a functional structural element 30. In FIG. 3C, the method of forming the functional film 36 and the type of the functional material are similar to those of the first embodiment, and further description thereof is omitted here.

According to the method of manufacturing the functional structural element according to the present embodiment, if there is a large difference between the lattice constant of the directionally solidified silicon substrate 32 and that of the functional film 36, then it is possible to improve the functionality of the functional film 36 by forming the buffer layer 34 of the material having the intermediate characteristics between those of directionally solidified silicon substrate and the functional material (for example, a material having the intermediate lattice constant between those of directionally solidified silicon and the functional material).

In the embodiments described above, the substrates 12 and 32 are made of directionally solidified silicon. However, it is also possible to adopt a configuration in which only the surface subjected to deposition of the film of functional material (functional material film) is made of directionally solidified silicon, for example.

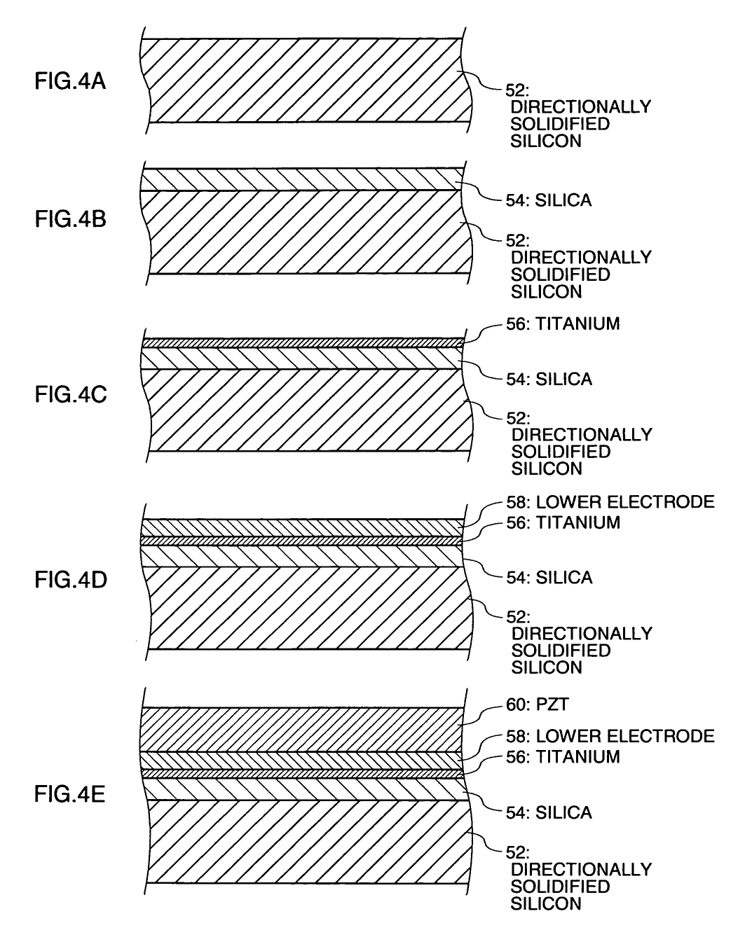

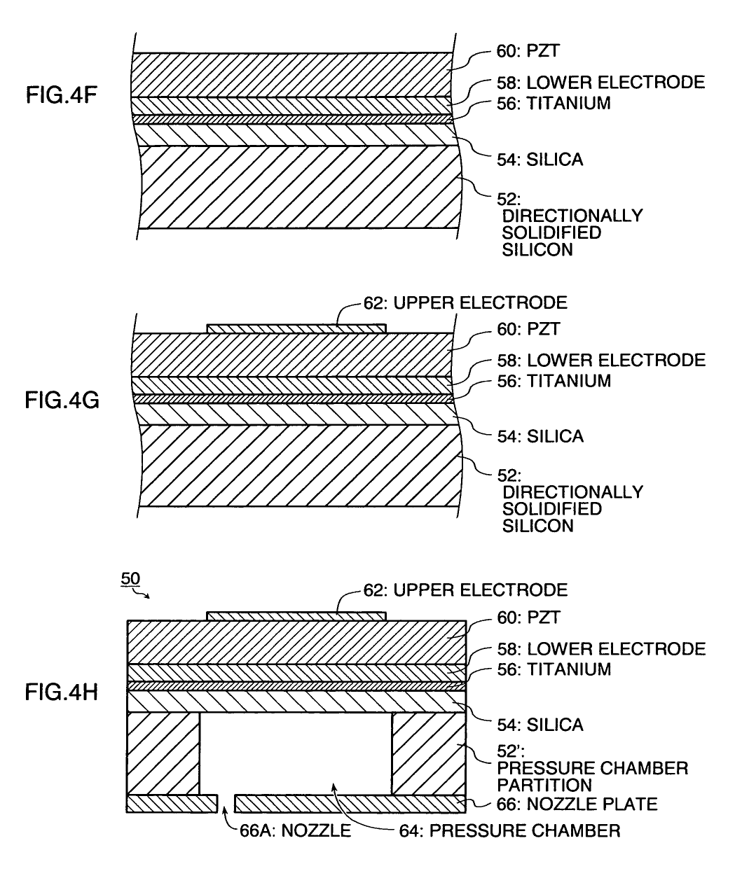

Next, a method of manufacturing a piezoelectric actuator by means of the method of manufacturing the functional structural element according to the present invention is described with reference to FIGS. 4A to 4H. FIGS. 4A to 4H are cross-sectional diagrams showing respective steps of a process for manufacturing a piezoelectric actuator. Although only one liquid ejection element is shown in FIGS. 4A to 4H, a plurality of liquid ejection elements are made from one substrate in actual practice.

Firstly, as shown in FIG. 4A, a substrate 52 is formed from directionally solidified silicon (columnar crystal silicon) manufactured by JEMCO INC. The substrate 52 is, for example, 50 mm square and has a thickness of 1 mm. A diaphragm 54 is formed on the substrate 52 as shown in FIG. 4B. The diaphragm 54 is made, for example, of silica (SiO₂), and is formed by bonding a silica layer onto the surface of the substrate 52, or by subjecting the surface of the substrate 52 to thermal oxidation processing. The surface of the diaphragm 54 is polished so as to have a surface roughness (Ra) of approximately 50 nm or less. The thickness of the diaphragm 54 after polishing is, for example, 500 nm. Silicon and silica constituting the substrate 52 and the diaphragm 54 have heat resistance and corrosion resistance. A material having “heat resistance” is a material in which no deformation, denaturalization or compositional change occur during the subsequent annealing step. Furthermore, a material having “corrosion resistance” is a material which is not dissolved or denaturalized by liquid (ink) used in the liquid ejection head, even if the liquid or ink has corrosive properties.

Next, as shown in FIGS. 4C and 4D, a titanium (Ti) bonding layer 56 of approximately 20 nm in thickness is formed by sputter deposition onto the diaphragm 54, and a lower electrode 58 made of a platinum (Pt) layer of approximately 200 nm in thickness is formed by sputter deposition onto the titanium bonding layer 56.

A piezoelectric film 60 is formed on the lower electrode 58, as shown in FIG. 4E. The piezoelectric film 60 is made, for example, of lead zirconate titanate (PbZr_{0.52}Ti_{0.48})₃) (PZT), and the piezoelectric film 60 is formed to a thickness of approximately 1 μm at room temperature, by means of the sol-gel method.

Next, the piezoelectric film 60 is subjected to a calcination process by laser annealing or electromagnetic heating. Thereby, the properties of the piezoelectric film 60 are improved and residual stress of the piezoelectric film 60 is removed. When carrying out the laser annealing and the electromagnetic heating, light or electromagnetic wave irradiation conditions are selected appropriately, and a non-continuous drive method using short pulses, or the like, is adopted. It is thus possible to heat the piezoelectric film 60 selectively, in such a manner that heat is not transmitted to the diaphragm 54, and the like. For example, if the laser annealing is used, then by using an ultra-short pulse laser such as a femtosecond laser, it is possible to suppress the generation of heat to a level which does not exceed the heat tolerance temperature of the polyurethane-based shape memory polymer (approximately several hundred degrees Celsius).

An upper electrode 62 is formed on the piezoelectric film 60, as shown in FIG. 4G The upper electrode 62 is made of platinum, for example, which is formed by the sputter deposition or the liftoff method. The size of the upper electrode 62 is 300 μm square, for example, and the thickness of the upper electrode 62 is 200 nm, for example.

Subsequently, a chromium (Cr) film (not shown) is deposited on the lower surface (in FIG. 4G) of the substrate 52, and the chromium film is patterned. The substrate 52 is etched by means of the reactive ion etching (RIE), taking the chromium film as a mask and using Freon (TM) gas (for example, tetrafluorocarbon (CF₄)). This etching is stopped by the lower surface (in FIG. 4G) of the diaphragm 54, and hence a flat etched surface is exposed. In other words, since Freon (TM) gas has high etching selectivity in respect of the material of the substrate 52 (i.e., silicon) and the material of the diaphragm 54 (i.e., silica), which functions as etching stopper, then it is possible to carry out highly accurate etching. The parts opened in the substrate 52 by the etching process are pressure chambers 64, and the sections remaining in the substrate 52 are pressure chamber partition walls 52′. Thus, the piezoelectric actuator including the diaphragm 54, the lower electrode 58, the piezoelectric film 60, and the upper electrode 62, is formed.

Apart from the RIE dry etching method described above, it is also possible to use, for example, wet etching, as the etching method for forming the pressure chambers 64 and the pressure chamber partition walls 52′. In the case of dry etching, it is preferable to select the type of the etching gas of which the etching ratio with respect to the substrate 52 and the diaphragm 54 is 2:1 (and more desirably, 5:1). In the case of wet etching, it is preferable to select the materials of the substrate 52 and the diaphragm 54, and the etching liquid, in such a manner that the etching ratio with respect to the substrate 52 and the diaphragm 54 is 5:1 (and more desirably, 10:1).

Finally, as shown in FIG. 4H, a nozzle plate 66 having nozzles 66A is bonded to the lower surface (in FIG. 4H) of the pressure chamber partitions 52′ by means of adhesive, thereby manufacturing a liquid ejection head 50.

According to the present embodiment, it is possible to form the piezoelectric actuators to a large size by using the substrate 52 made of directionally solidified silicon having a large surface area. By means of the liquid ejection head having the piezoelectric actuators of a large size, it is possible to print onto paper of a large size by means of a single pass, for example. Moreover, even when manufacturing piezoelectric actuators of a small size, it is possible to manufacture a large amount of piezoelectric actuators from one substrate 52, in one manufacturing process, and hence the cost of the piezoelectric actuators can be reduced.

The present invention can be applied to memory elements, piezoelectric elements such actuators, pyroelectric elements such as infrared sensors, passive elements such as capacitors and inductors, optical elements such as photo switches, superconducting elements such as SQUID, photoelectric transducers, micro magnetic elements such as magnetic heads, semiconductor elements such as TFT, and equipment which uses these elements.

It should be understood, however, that there is no intention to limit the invention to the specific forms disclosed, but on the contrary, the invention is to cover all modifications, alternate constructions and equivalents falling within the spirit and scope of the invention as expressed in the appended claims.

What is claimed is:

1. A functional structural element, comprising:
a substrate member which has a surface made of directionally solidified silicon; and
a functional structural body which is made of a functional material and is formed on the surface of the substrate member.

2. The functional structural element as defined in claim 1, wherein the surface of the substrate member is a Si(001) surface.

3. The functional structural element as defined in claim 1, further comprising:
a buffer layer which is formed between the substrate member and the functional structural body,
wherein the functional material is epitaxially grown onto the buffer layer and forms the functional structural body.

4. The functional structural element as defined in claim 3, wherein the buffer layer is made of a material including at least one of yttria-stabilized zirconia, celia, magnesium aluminate, and alumina.

5. The functional structural element as defined in claim 1, wherein the functional material includes at least one of a piezoelectric material, a pyroelectric material and a ferroelectric material.

6. The functional structural element as defined in claim 1, wherein the functional material includes a superconducting material.

7. The functional structural element as defined in claim 1, wherein the functional material includes a magnetic material.

8. The functional structural element as defined in claim 1, wherein the functional material includes a semiconductor material.

9. A method of manufacturing a functional structural element, comprising the steps of:
forming a substrate member having a surface made of directionally solidified silicon; and
forming a functional structural body made of a functional material onto the surface of the substrate member.

10. A method of manufacturing a functional structural element, comprising the steps of:
forming a substrate member having a surface made of directionally solidified silicon;
forming a buffer layer onto the surface of the substrate member; and
forming a functional structural body by epitaxially growing a functional material onto the buffer layer.

11. A substrate for manufacturing a functional structural body, the substrate comprising:
a substrate member which has a surface made of directionally solidified silicon; and
a buffer layer which is formed on the surface of the substrate member, a functional structural body to be formed on the buffer layer.

12. The substrate as defined in claim 11, wherein the buffer layer is made of a material including at least one of yttria-stabilized zirconia, celia, magnesium aluminate, and alumina.
